(19) United States
(12) Patent Application Publication
(10) Pub. No.: US 2005/0226441 A1
(43) Pub. Date: Oct. 13, 2005

(54) Speaker system

(75) Inventors: Shoji Tanaka, Kobe-shi, Hyogo (JP); Churo Sato, Senboku-gun Osaka (JP); Isao Kuramitsu, Hirakata-shi Osaka (JP)

Correspondence Address: RATNERPRESTIA, P O BOX 980, VALLEY FORGE, PA, 19482-0980, US

(73) Assignee: Matsushita Electric Industrial Co., Ltd., Osaka (JP)

(21) Appl. No.: 10/515,878

(22) PCT Filed: Jan. 29, 2004
(86) PCT No.: PCT/JP04/00820

§ 371 Date: Nov. 24, 2004

(30) Foreign Application Priority Data
Jan. 30, 2003 (JP) 2003-021814

(51) Int. Cl. H03G 5/00; H04R 29/00

(52) U.S. Cl. 381/99; 381/98; 381/59

(57) ABSTRACT

A speaker system which has a plurality of speaker units arranged and which realizes improvements in the directive characteristics of the array direction in a high frequency band and in the total acoustic energy is provided. The speaker system comprising: a first speaker unit; a second speaker unit connected in series with the first speaker unit; and a capacitor connected in parallel with the second speaker unit. The input current to the second speaker unit in a high frequency band attenuates whereas the input current to the first speaker unit in a high frequency band increases.

### TECHNICAL FIELD

The present invention relates to a speaker system, which is intended to improve the characteristics in a high frequency band although a plurality of speaker units are arrayed.

### BACKGROUND ART

In recent years, a home-theater device capable of enjoying movies as impressively at home as at theaters has come into wide use. The speaker system for the home-theater device has a general configuration of: totally five small satellite speaker systems for reproducing front two-channels, center one-channel and surround two-channels; and one sub-woofer. Especially, the satellite speaker systems required are so many as five so that they have to be lowered as much as possible in cost and size. It is also desired to increase the power for the impressive reproduction. A high power can be obtained if the multi-way configuration uses large-diameter woofers. However, this configuration seriously increases not only the cost but also the size.

If a plurality of small-diameter full-range speaker units are arrayed, a high power can be attained at a low cost. In other words, the power can be easily increased in proportion to the number of the full-range speaker units. In the aspect of the size, it is possible to prevent the width of the cabinet from becoming as large as that of the case using the large-diameter woofer. In the case of arraying the speaker units, however, it has been known in the related art that the characteristics are deteriorated in the high frequency band, namely, that the directive characteristics in the array direction are deteriorated. This will be described with reference to FIG. 7. In FIG. 7, two speaker units 31 and 32 having identical characteristics are arrayed and mounted in cabinet 33. Speaker units 31 and 32 are connected in parallel, as viewed from input terminals 35.

The point on the center axis in the array direction of speaker units 31 and 32, that is, the point of the front face is designated by Pc. The attainable distance from speaker unit 31 to point Pc is equal to that from speaker unit 32 to point Pc. At this point Pc, no discrepancy in phase occurs between the sound waves to arrive from speaker unit 31 and the sound waves to arrive from speaker unit 32. Therefore, these two sound waves neither interfere nor weaken each other even in the high frequency band so that the sound pressure level in the high frequency band does not become lower. A point offset from the center with respect to the array direction is designated by P. At this point P, attainable distance L1 from speaker unit 31 and attainable distance L2 from speaker unit 32 are different. In the high frequency band of an especially short wave length, therefore, a high phase difference occurs between the sound wave to arrive from speaker unit 31 and the sound wave to arrive from speaker unit 32. The sound waves interfere each other to lower the sound pressure level at point P so that the directive characteristics of the speaker units in the array direction are deteriorated.

A method proposed for solving that problem is described in FIG. 14•12, on page 457 of “Speaker System” (2nd Vol.) edited by Takeo YAMAMOTO. FIG. 8 presents a configuration of the speaker system described in that book. This is the speaker system called the “Line arrayed type”, in which multiple speaker units are arrayed. In FIG. 8, speaker units 41a and 41b, and 42a and 42b having identical characteristics are arrayed and mounted in cabinet 43. These individual speakers are connected in parallel, as viewed from input terminals 45, and low-pass filters 47a and 47b are inserted into speaker units 42a and 42b. As viewed from a point off set from the center with respect to the array direction, speaker units 42a and 42b arranged at the two ends in cabinet 43 have the largest distance difference. With the configuration shown in FIG. 8, however, the input voltages attenuate in the high frequency band in speaker units 42a and 42b so that the sound waves to interfere with each other with the large phase difference are weakened. Therefore, it is possible to improve the deterioration of the directive characteristics of the speaker units in the array direction.

With the aforementioned configuration of the related art, however, the total acoustic energy in the high frequency band attenuates. A problem is that the sound pressure level especially in the vicinity of the center axis of the array direction, i.e., the sound pressure level in the vicinity of the front face of the speaker system attenuates. This problem will be described with reference to FIG. 9 and FIG. 10. In FIG. 9, the aforementioned related art is applied to the speaker system described with reference to FIG. 7. FIG. 10 illustrates the frequency characteristics near the front face of the speaker system of FIG. 9.

In FIG. 9, the simplest low-pass filter or choke coil 37 is connected in series with second speaker unit 32. In the high frequency band, therefore, the input voltage of second speaker unit 32 attenuates more than that of first speaker unit 31. Therefore, the interference between the individual sound waves to arrive from individual speaker units 31 and 32 at a point missing the vicinity of the front face is reduced to improve the directive characteristics. In the high frequency band, however, the input voltage of second speaker unit 32 attenuates to that the acoustic energy to be radiated by second speaker unit 32 attenuates. As a result, the total acoustic energy of first speaker unit 31 and second speaker unit 32 also attenuates in the high frequency band. This causes a defect that the sound pressure level near the front face attenuates.

FIG. 10 illustrates this behavior. In FIG. 10, the abscissa indicates a frequency, and the ordinate indicates the sound pressure level (as designated by SPL in FIG. 10). In the vicinity of the front face, the sound waves to arrive from individual speaker units 31 and 32 are in phase. If the sound pressure level (as designated by SPL(31) in FIG. 10) and the sound pressure level (as designated by SPL(32) in FIG. 10) are at the same level, as illustrated in FIG. 10, the total sound pressure level (as designated by SPL(31+32) in FIG. 10) is their addition and becomes higher by about 6 dB. In the high frequency band, however, sound pressure level SPL(32) attenuates so that sound pressure level SPL(31+32) attenuates closer to the level of only sound pressure level SPL(31), Therefore, the attenuation is lower by about 6 dB than that of the lower frequency band.

Thus, the speaker system of the aforementioned configuration of the related art is troubled by a problem that the improvement in the directive characteristics in the array direction causes an attenuation in the total acoustic energy in the high frequency band. According to the configuration of the related art, therefore, the sound quality is short of a high range in the vicinity of the front face. Moreover, the low-pass filter is indispensable so that at least the choke coil has to be added to invite a considerable increase in cost.

### DISCLOSURE OF THE INVENTION

A speaker system comprising:
a first speaker unit;
a second speaker unit connected in series with the first speaker unit; and
a capacitor connected in parallel with the second speaker unit,
wherein the input current to the second speaker unit in a high frequency band is attenuated whereas the input current to the first speaker unit in a high frequency band is increased.

### BRIEF DESCRIPTION OF THE DRAWINGS

FIG. 1A is a configuration diagram of a speaker system of Embodiment 1 of the invention.

FIG. 1B is a perspective view of the speaker system of Embodiment 1 of the invention.

FIG. 2 is a frequency characteristic diagram near the front face of the speaker system of Embodiment 1 of the invention.

FIG. 3 is a circuit diagram of the fundamental principle of the speaker system of Embodiment 1 of the invention.

FIG. 4 is a characteristic diagram of the actual frequency of the speaker system of Embodiment 1 of the invention.

FIG. 5 is a configuration diagram of a speaker system of Embodiment 2 of the invention.

FIG. 6 is a configuration diagram of a speaker system of Embodiment 3 of the invention.

FIG. 7 is a configuration diagram of a speaker system of the related art.

FIG. 8 is a configuration diagram of another speaker system of the related art.

FIG. 9 is a configuration diagram of another speaker system of the related art.

FIG. 10 is a frequency characteristic diagram near the front face of the speaker system of the related art.

FIG. 11 is a characteristic diagram of the actual frequency of the speaker system of the related art.

### DETAILED DESCRIPTION OF THE PREFERRED EMBODIMENTS

The invention contemplates to solve the aforementioned problems of the related art and to provide a speaker system, in which a plurality of speaker units are arranged and which is improved in the directive characteristics of the array direction in a high frequency band. The invention further contemplates to provide a speaker system which is improved in the total acoustic energy in the high frequency band and which has a little increase in cost.

### Embodiment 1

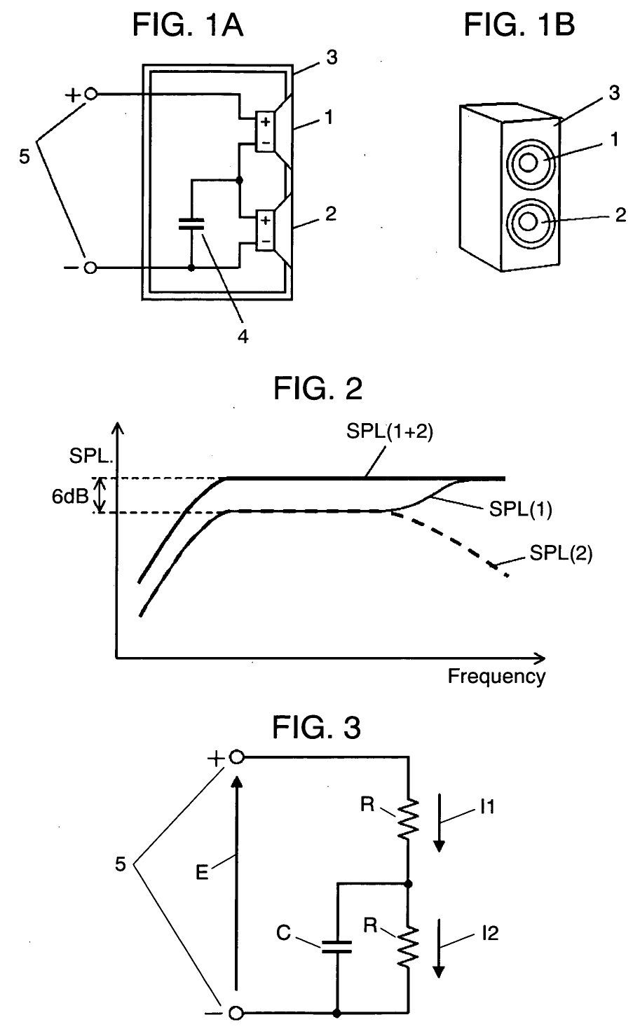

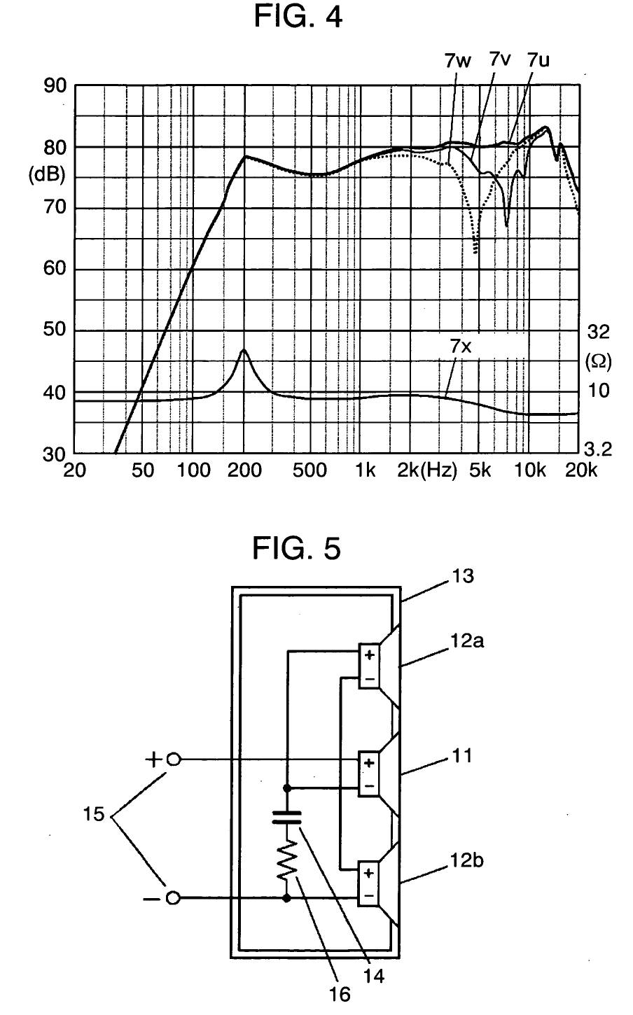

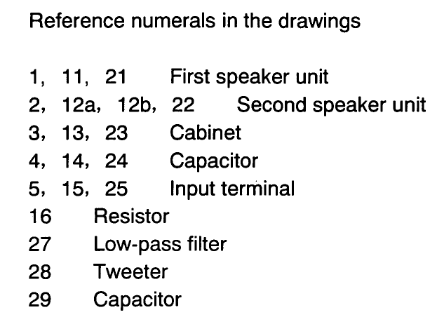

A speaker system of Embodiment 1 of the invention will be described with reference to FIG. 1A, FIG. 1B, FIG. 2, FIG. 3, FIG. 4 and FIG. 11. FIG. 1A shows a configuration of the speaker system of Embodiment 1, and FIG. 1B shows a perspective view of the speaker system of Embodiment 1. In FIG. 1A and FIG. 1B, first speaker unit 1 and second speaker unit 2 are arrayed and mounted in cabinet 3. With respect to input terminals 5, speaker unit 1 and speaker unit 2 are connected in series with each other. Capacitor 4 is connected in parallel with second speaker unit 2.

The components of the speaker system will be specifically described in the following. First speaker unit 1 and second speaker unit 2 are full-range units, which are give the same specifications and frequency characteristics having a diameter of 6.5 cm and an impedance of 4 Ω. This speaker system has a nominal impedance of 8 Ω. Cabinet 3 is a sealed type and has first speaker unit 1 and second speaker unit 2 mounted therein with a center spacing of about 8 cm. Capacitor 4 has a capacity of 5.6 μF.

The actions of the speaker system thus constructed will be described with reference to FIG. 2 and FIG. 3. FIG. 2 shows the frequency characteristics near the front face of the speaker system of Embodiment 1. In FIG. 2, the abscissa indicates a frequency, and the ordinate indicates a sound-pressure level (as designated by SPL in FIG. 2). FIG. 2 illustrates the sound pressure frequency characteristic (as designated by SPL(1) in FIG. 2) of first speaker unit 1, the sound pressure frequency characteristic (as designated by SPL(2) in FIG. 2) of second speaker unit 2, and the total sound pressure frequency characteristic (as designated by SPL(1+2) in FIG. 2) of first speaker unit 1 and second speaker unit 2. The sound waves to arrive from individual speaker units 1 and 2 at the vicinity of the front face are in phase. In the low frequency band where sound pressure frequency characteristics SPL(1) and sound pressure frequency characteristics SPL(2) are at the same level, sound pressure frequency characteristics SPL(1+2) are raised by about 6 dB by their addition. This point is similar to that of the aforementioned speaker system of the related art.

In the invention, first speaker unit 1 and second speaker unit 2 are connected in series with respect to input terminals 5. Therefore, the input voltages to be applied to individual speaker units 1 and 2 are those which are divided from the voltage of input terminals 5 at the ratio of the two end impedances of individual speaker units 1 and 2. In Embodiment 1, both speaker units 1 and 2 have the impedance of 4 Ω. In the low frequency band, therefore, the voltage division ratio to individual speaker units 1 and 2 is 1:1 so that the same input voltage is applied to individual speaker units 1 and 2. Since capacitor 4 is connected in parallel with second speaker unit 2, moreover, the impedance of capacitor 4 is lowered in the high frequency band so that the synthesized parallel impedance of second speaker unit 2 and capacitor 4 becomes smaller than the impedance of first speaker unit 1. In the high frequency band, therefore, the signal voltage division ratio to second speaker unit 2 becomes smaller whereas the signal voltage division ratio to the first speaker unit 1 becomes larger. In the high frequency band, therefore, the input voltage of the second speaker unit attenuates whereas the input voltage of the first speaker unit augments. In other words, capacitor 4 shorts second speaker unit 2 in the frequency band where the impedance of capacitor 4 becomes very small. As a result, the impedance, as viewed from input terminals 5, of the entire circuit approaches the impedance of only first speaker unit 1 so that the electric current to flow through first speaker unit 1 becomes more than that in the low frequency band. By this action, the input current of second speaker unit 2 attenuates more than first speaker unit 1 in the high frequency band so that the sound-pressure level of second speaker unit 2 becomes lower than that of first speaker unit 1. As a result, the interference between the individual sound waves to arrive from individual speaker units 1 and 2 at the point missing the vicinity of the front face is reduced to improve the directive characteristics. As illustrated in FIG. 2, sound pressure frequency characteristics SPL(1) increases contrary to the attenuation of sound pressure frequency characteristics SPL (2) in the high frequency band. Therefore, sound pressure frequency characteristics SPL(1+2) do not attenuate so that the total acoustic energy can be improved better than that of the related art.

This principle action will be analyzed and explained with reference to FIG. 3. FIG. 3 is a circuit diagram of the fundamental principle of the speaker system of the invention. In FIG. 3: the resistance corresponding to the impedance of first speaker unit 1 is designated by R; the resistance corresponding to the impedance of second speaker unit 2 is designated by R; the electric current to flow through first speaker unit 1 is designated by I1; the electric current to flow through second speaker unit 2 is designated by I2; and the voltage to be applied to input terminals 5 is designated by E. Moreover, an angular frequency is designated by ω (ω=2πf, if the frequency is designated by f). The impedance, as seen from input terminals 5, of the entire circuit is designated by Z. In this case: (Formula 1) holds for impedance Z; (Formula 2) holds for electric current I1; and (formula 3) holds for electric current I2. Moreover, (Formula 4) holds for the total electric current of electric current I1 and electric current I2.
Z=R(jωCR+2)/(jωCR30 1) (Formula 1)
I1=E(jωCR+1)/R(jωCR+2) (Formula 2)
I2=E/R(jωCR+2) (Formula 3)

$$\begin{matrix}I1 + I2 = E \{ ( jω C R + 1 ) + 1 \} / R ( jω C R + 2 ) \\ = E / R \end{matrix} \qquad ( Formula 4 )$$

In case the frequency is low, that is, in case the ω is near 0, the value I1 expressed by (Formula 2) approaches E/2R, and value I2 expressed by (Formula 3) approaches E/2R. That is, the same electric current flows through individual speaker units 1 and 2. In case the frequency is high, that is, value ω is ∞, electric current I1 expressed by (Formula 2) is E/R, and electric current I2 expressed by (Formula 3) is 0. That is, the electric current does not flow through second speaker unit 2, but an electric current twice as high as that in the low frequency flows through first speaker unit 1.

It is also found from (Formula 4) that the total electric current takes constant value E/R independently of the frequency. It is needless to say that the driving force of the speaker unit is proportional to the electric current to flow through the voice coil, and that the output voice pressure is also proportional to that electric current. It follows that the total of the output sound pressures of first speaker unit 1 and second speaker unit 2 is proportional to the total of the electric current to flow through the individual speaker units. As a result, no attenuation occurs in the frequency of high total sound-pressure level SPL(1+2), as illustrated in FIG. 2.

The actual effects of the invention will be described by comparing FIG. 4 and FIG. 11. FIG. 4 is a characteristic diagram of the actual frequency of the speaker system of Embodiment 1 of the invention. FIG. 11 is a characteristic diagram of the actual frequency of the case, in which the capacitor 4 is eliminated from the speaker system of Embodiment 1. The remaining configurations are absolutely identical to those of Embodiment 1. In other words, FIG. 11 corresponds to the speaker system of the related art which has been described with reference to FIG. 7.

In FIG. 4 and FIG. 11, the abscissa indicates the frequency, and the ordinate indicates the sound pressure. Sound pressure 7u and sound pressure 38u are the sound-pressure frequency characteristics at the front face (at 0 degrees, i.e., in the same direction as the center axis). Sound pressure 7v and sound pressure 38v are the sound-pressure frequency characteristics at a point which is displaced upward by 7.5 degrees from the center axis in the speaker unit array direction. Sound pressure 7w and sound pressure 38w are the sound-pressure frequency characteristics at a point which is displaced upward by 15 degrees from the center axis in the speaker unit array direction. Impedance 7x and impedance 38x are the impedance frequency characteristics. In any case, the distance from the center of the front face of the speaker system to the microphone is 2 m.

It is found from FIG. 11 that the speaker system of the related art has a large attenuation and poor directive characteristics at sound pressure 38v (i.e., the sound-pressure frequency characteristics at a point displaced upward by 7.5 degrees from the center axis) and at sound pressure 38w (i.e., the sound-pressure frequency characteristics at a point displaced upward by 15 degrees from the center axis). In view of FIG. 4, on the contrary, the speaker system of Embodiment 1 is drastically improved from the related art both at sound pressure 7v (i.e., the sound-pressure frequency characteristics at a point displaced upward by 7.5 degrees from the center axis) and at sound pressure 7w (i.e., the sound-pressure frequency characteristics at a point displaced upward by 15 degrees from the center axis). It is also found that the frequency characteristic at sound pressure 7u (i.e., the sound-pressure frequency characteristics in the same direction as the center axis, namely at 0 degrees) does not attenuate. This means that the directive characteristics are improved without any attenuation of the sound pressure level at 0 degrees, and that the total acoustic energy is improved. This improvement can also be explained from the aforementioned analysis. Without capacitor C, value I1 expressed by (Formula 2) and value I2 expressed by (Formula 3) are I1=I2=E/2R. If the total of the powers to be applied to individual resistors R is designated by P, therefore, this total power P takes a value of E²/2R, as expressed by (Formula 5).
P=R×11²+R12²=E²/2R (Formula 5)
In case capacitor C is connected, in a high frequency band, value I1 expressed by (Formula 2) approaches E/R, and value I2 expressed by (Formula 3) approaches 0. If the total of the powers to be applied to individual resistors R is designated by P, therefore, this total power P increases to two times as high as that of the case of no capacitor C, as expressed by (Formula 6).
P=E²/R (Formula 6)
In short, the total of the signal powers to be applied to individual speaker units 1 and 2 in the high frequency band increases to two times as high as that of the related art. The acoustic output radiated from the speaker unit is proportional to the input electric power, although needless to say, the total acoustic energy in the high frequency band is improved by the invention better than the related art.

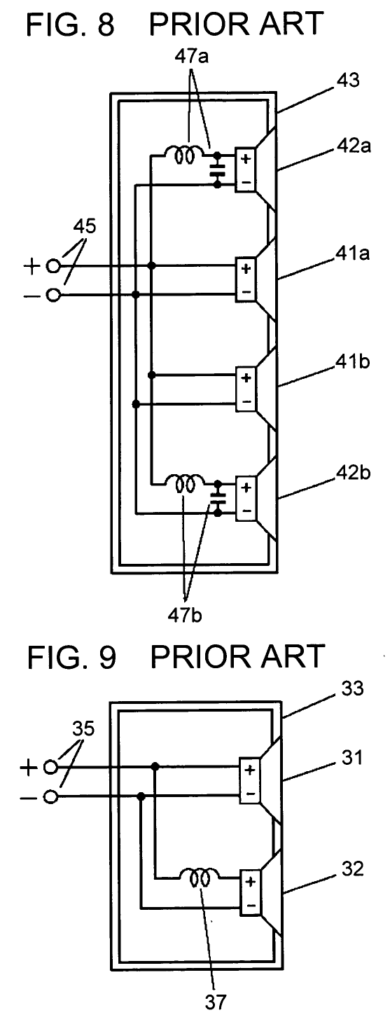

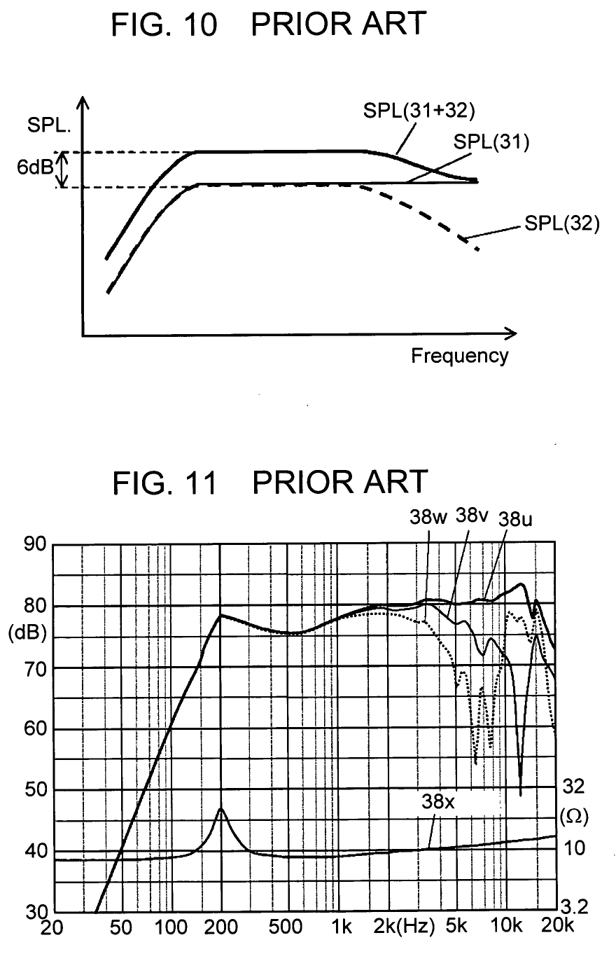

Noting impedance 7x of FIG. 4 and impedance 38x of FIG. 11, it is found that the speaker system of Embodiment 1 has a low impedance in the high frequency band and that the electric current of the first speaker unit 1 increases. Moreover, the speaker system of the related art intended to improve the directive characteristics, as described in FIG. 8 and FIG. 9, needs at least the choke coil. On the contrary, Embodiment 1 uses only one capacitor so that it has a merit of a little increase in cost. This is because the capacitor is lower in unit cost than the choke coil and has a small weight but no fear of any induced magnetic field to the outside so that it can be arranged in the speaker system at a lower cost than that for the choke coil.

According to Embodiment 1 thus far described, therefore, it is possible to realize the speaker system, which can improve the directive characteristics in the array direction in the high frequency band and the total acoustic energy in the high frequency band and which has a low cost increase.

Embodiment 1 has one first speaker unit 1 and one second speaker unit 2, one or both of which may be configured of a plurality of speaker units. This configuration will be described in connection with Embodiment 2.

In Embodiment 1, on the other hand, capacitor 4 is directly connected in parallel with second speaker unit 2, but the series connection of capacitor 4 with a resistor may also be connected with second speaker unit 2. This connection will also be described in connection with Embodiment 2.

In Embodiment 1, moreover, first speaker unit 1 and second speaker unit 2 connected in series are directly connected with input terminals 5. It is, however, naturally possible to interpose such a low-frequency-signal cutting capacitor of a high capacity between the speaker unit and input terminals 5 as to protect the speaker unit against a low-frequency-range excessive input. The effect of the invention can be attained, if the first speaker unit and the second speaker unit are connected in series, as viewed from the input terminals, and if the capacitor is connected in parallel with the second speaker unit. In other words, the fundamental effects are unvaried, even if an element such as the capacitor or the coil is interposed between the individual series-connected speaker units and the coil.

This reason is as follows. The input current attenuating action of the second speaker unit in the high frequency band and the input current increasing action of the first speaker unit is caused by the ratio of the input voltage of the second speaker unit having the parallel-connected capacitor to the input voltage of the first speaker unit, as has been described hereinbefore. In other words, these input current attenuating action and input current increasing action are caused by the signal voltage division ratio of the individual speaker units, and this voltage division ratio itself is unvaried even if the element is interposed between the input terminals and those speaker units. This is because that voltage division ratio is univocally determined by the synthesized parallel impedance of the capacitor and the second speaker unit connected in parallel and by the impedance of the first speaker unit but is independent of the element interposed between the speaker units and the input terminals.

In Embodiment 1, moreover, first speaker unit 1 and second speaker unit 2 are given the same frequency characteristic and impedances, but they may also be given different characteristics and specifications. For example, second speaker unit 2 having parallel-connected capacitor 4 may be so characterized that the high range is more attenuated than first speaker unit 1. In addition, second speaker unit 2 may has a larger diameter than that of first speaker unit 1. Moreover, similar effects can be obtained even if first and second speaker units 1 and 2 have different impedances.

By giving the same frequency characteristic and impedances to first speaker unit 1 and second speaker unit 2, however, it is unnecessary to discriminate the speaker unit to be connected with capacitor 4. This eliminates the danger that the desired characteristics cannot be attained when the speaker unit is mounted in a wrong position at the assembling time of the speaker system. In addition, first speaker unit 1 and second speaker unit 2 can be given the same specifications so that they can be commonly used. Thus, it is possible to realize the speaker system which is excellent in mass production.

In Embodiment 1, moreover, first speaker unit 1 and second speaker unit 2 are full-range units, but the invention can also be applied to woofer or mid-range units in a multi-way speaker system. This will be described in connection with Embodiment 3.

In Embodiment 1, moreover, first speaker unit 1 and second speaker unit 2 are mounted in cabinet 3. It is, however, needless to say that the cabinet can be dispensed with in some type of the speaker system.

In Embodiment 1, capacitor 4 has the capacity of 5.6 μF, which is not limitative. This capacity may be designed by considering the impedances of the individual speaker units, the interval of the array, what frequency band the directive characteristics or the acoustic energy is to be improved from, the minimum impedance permissible for the entire speaker system, and soon. The frequency, at which the input current attenuating effect of second speaker unit 2 and the input current increasing effect of the first speaker unit 1 appear, is lowered in proportion to the produce the impedance of second speaker unit 2 and the capacity of capacitor 4. By increasing this product the more, the effect to improve the directive characteristics and the acoustic energy can be obtained from the lower frequency band.

With the larger product, however, the input power of the first speaker unit becomes high from the lower frequency band so that the first speaker unit takes a disadvantage in the permissible input. It is better that this point is considered in the design.

It is natural that the invention should not be limited to the embodiments thus far described. The diameters or impedances of the individual speaker units, the values of the used elements, the arrangement interval of the individual speaker units and so on should not be limited the aforementioned numerical values.

### Embodiment 2

A speaker system of Embodiment 2 of the invention will be described with reference to FIG. 5. In FIG. 5, first speaker unit 11, second speaker unit 12a and second speaker unit 12b are arrayed and mounted in cabinet 13. Embodiment 1 shown in FIG. 1A and FIG. 1B has one second speaker unit, but Embodiment 2 shown in FIG. 5 has two second speaker units. First speaker unit 11 is arranged at the center between second speaker units 12a and 12b. All of the individual speaker units are given identical specifications having a diameter of 6.5 cm and an impedance of 2.5 Ω. As viewed from input terminals 15, first speaker unit 11 and second speaker units 12a and 12b are connected in series. Capacitor 14 is connected through resistor 16 in parallel with second speaker unit 12a and second speaker unit 12b connected in series. Capacitor 14 has a capacity of 6.8 μF, and resistor 16 has a resistance of 2.2 Ω. The nominal impedance of the speaker system is 8 Ω.

With the configuration thus far described, it is effective as in Embodiment 1 to improve the directive characteristics and the acoustic energy of the speaker units in the high frequency band. In addition, a speaker system of higher power can be realized by using the three identical speaker units. In this Embodiment, moreover, resistor 16 is connected in series with capacitor 14 so that the minimum impedance of the speaker system in the high frequency band can be so adjusted as not to become excessively low.

In Embodiment 2, second speaker units 12a and 12b having the impedance of 2.5 Ω are connected in series. However, similar effects can be obtained, even if second speaker units 12a and 12b are given an impedance of 10 Ω and connected in parallel.

Moreover, Embodiment 2 uses two second speaker units, but various designs can be made by using two or more first speaker units or by increasing the number of the second speaker units more.

In case multiple second speaker units are used, still moreover, they can be arrayed in various manners, in which they are not only arrayed in a row as in Embodiment 2 but also arranged around the first speaker unit. If the configuration of the invention is applied to the case in which the speaker units are arrayed in the latter manner, it is possible to improve the directive characteristics in both the vertical direction and the horizontal direction.

In Embodiment 2, moreover, second speaker units 12a and 12b are symmetrically arranged on the two sides of first speaker unit 11 so that the directive characteristics can be made symmetric with respect to the center of the array direction of the speaker units. In case the individual speaker units are arrayed in the horizontal direction, for example, the directive characteristics of the speaker system are symmetric in the horizontal direction. This speaker unit arrangement is called the “virtual coaxial configuration”, which is known to have an effect to improve the balance of the radiation sound field of the speaker system. However, it is needless to say that the arrangement of the individual speaker units 11, 12a and 12b may be modified according to the application.

In Embodiment 2, moreover, capacitor 14 is connected through resistor 16 in parallel with second speaker units 12a and 12b. Another circuit configuration can naturally be made. Depending on the circuit configuration, moreover, the capacitor can also be connected in parallel with the first speaker unit. Then, the values of the individual capacitors may be so properly designed that the effect of the capacitor connected in parallel with the first speaker unit may be superior. In short, the values of the individual capacitors may be so properly designed as not to deteriorate the input current increasing effect of the first speaker unit in the high frequency band.

Still moreover, it is natural that the invention should not be limited to the embodiments thus far described. The diameters or impedances of the individual speaker units, the values of the used elements, the arrangement interval of the individual speaker units and so on should not be limited the aforementioned numerical values.

### Embodiment 3

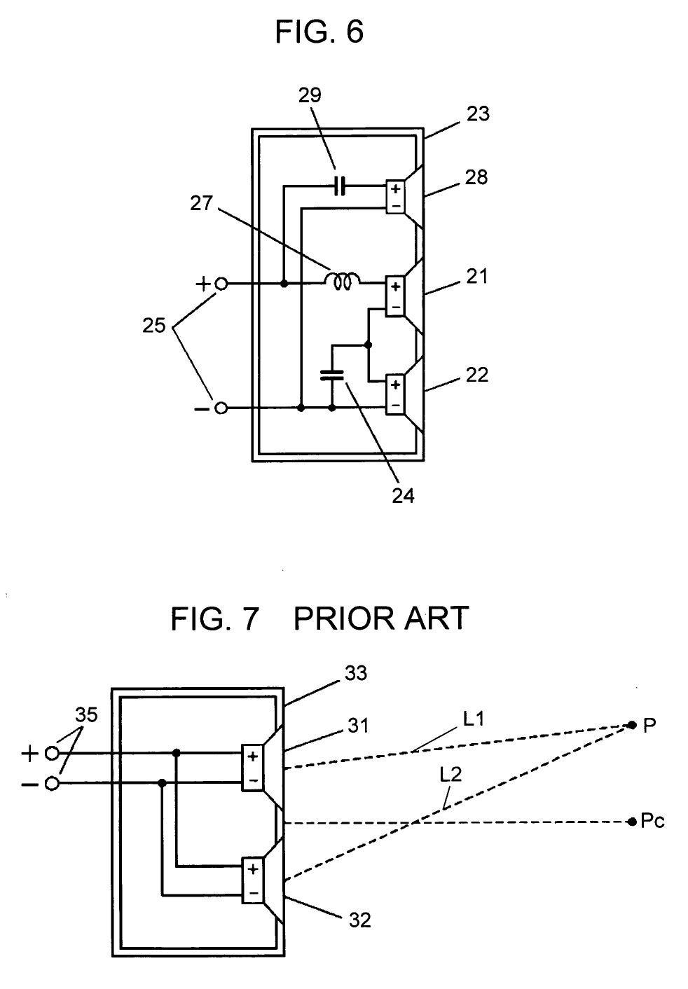

A speaker system of Embodiment 3 of the invention will be described with reference to FIG. 6. In FIG. 6, first speaker unit 21 and second speaker unit 22 are not full-range units but woofers. First speaker unit 21, second speaker unit 22 and tweeter 28 are arrayed and mounted in cabinet 23. Capacitor 24 is connected in parallel with second speaker unit 22. Choke coil 27 is a choke coil of the low-pass filter of a network. As viewed from input terminals 25, first speaker unit 21 and second speaker unit 22 are connected in series through choke coil 27. Capacitor 29 is such a capacitor of the high-pass filter of the network as is interposed between tweeter 28 and input terminals 25.

With the configuration thus far described, by the action like that described in Embodiment 1, the input current of second speaker unit 22 in the high frequency band attenuates, and the input current of first speaker unit 21 in the high frequency band increases. It is, therefore, effective to improve the directive characteristics and the acoustic energy in the speaker unit array direction of first speaker unit 21 and second speaker unit 22.

In Embodiment 3, first speaker unit 21 and second speaker unit 22 connected in series are connected with input terminals 25 through choke coil 27. With this, too, the fundamental effect of the invention is unvaried. This effect has been described in connection with Embodiment 1. Even in case a plurality of woofers are used in the multi-way speaker system, according to the speaker system of Embodiment 3, it is possible to improve the directive characteristics and the acoustic energy near the upper limit of the reproduced band of the woofers in the array direction.

In Embodiment 3, first speaker unit 21 and second speaker unit 22 are woofers. However, the invention can be applied to a plurality of mid-ranges used, for example, in a three-way speaker system. The invention can also be applied to a plurality of tweeters used, for example.

It is natural that the invention should not be limited to the embodiments thus far described. The diameters or impedances of the individual speaker units, the values of the used elements, the arrangement interval of the individual speaker units and so on should not be limited the aforementioned numerical values.

According to the speaker system of the invention thus far described, in the high frequency band, the sound pressure level of the second speaker unit is lower than that of the first speaker unit. Therefore, the interference between the individual sound waves to arrive from the individual speaker units at the point missing the vicinity of the front face is lowered to improve the directive characteristics in the array direction. Moreover, the total of the signal powers to be applied to the individual speaker units in the high frequency band increases to improve the total acoustic energy in the high frequency band. In addition, the speaker system of the related art intended to improve the directive characteristics needs at least the choke coil. On the contrary, what is needed in the invention is the capacitor so that the cost increase is far smaller.

According to the speaker system of the invention, moreover, the first speaker unit and/or the second speaker unit can be configured of a plurality of speaker units so that a speaker system of higher power can be realized.

According to the speaker system of the invention, moreover, the frequency characteristic and the impedances of the first speaker unit and the second speaker unit are made substantially identical so that the speaker unit to be connected with the capacitor need not be discriminated. The first speaker unit and the second speaker unit can be given the identical specifications so that they can be commonly used. Thus, it is possible to realize the speaker system which is excellent in mass production.

This invention has very high practical value as the above explanation.

### INDUSTRIAL APPLICABILITY

The speaker system according to the invention can improve the directive characteristics of the array direction in the high frequency band and the total acoustic energy in the high frequency band, although a plurality of speaker units are arranged. Moreover, the speaker system has a little increase in cost.

1. A speaker system comprising:
a first speaker unit;
a second speaker unit connected in series with the first speaker unit; and
a capacitor connected in parallel with the second speaker unit,
wherein the input current to the second speaker unit in a high frequency band is attenuated whereas the input current to the first speaker unit in a high frequency band is increased.

2. A speaker system as set forth in claim 1,
wherein at least one of the first speaker unit and the second speaker unit is configured to include a plurality of speaker units.

3. A speaker system as set forth in claim 1,
wherein the first speaker unit and the second speaker unit are substantially identical in frequency characteristic and impedances.

4. A speaker system as set forth in claim 1, further comprising:
a resistor connected in series with the capacitor,
wherein the capacitor and the resistor are connected in a series-connected state in parallel with the second speaker unit.

5. A speaker system as set forth in claim 1,
wherein the first speaker unit and the second speaker unit are full-range units.

6. A speaker system as set forth in claim 1,
wherein the first speaker unit and the second speaker unit are woofer units or mid-range units.

7. A speaker system as set forth in claim 2,
wherein one of the first speaker unit and the second speaker unit is configured to include a plurality of speaker units whereas the other is configured to include one speaker unit; and
wherein the plural speaker units are arranged around the one speaker unit.

8. A speaker system as set forth in claim 2,
wherein the first speaker unit and the second speaker unit are substantially identical in frequency characteristic and impedances.

9. A speaker system as set forth in claim 2, further comprising:
a resistor connected in series with the capacitor,
wherein the capacitor and the resistor are connected in a series-connected state in parallel with the second speaker unit.

10. A speaker system as set forth in claim 2,
wherein the first speaker unit and the second speaker unit are full-range units.

11. A speaker system as set forth in claim 2,
wherein the first speaker unit and the second speaker unit are woofer units or mid-range units.
